(19) United States
(12) Patent Application Publication
(10) Pub. No.: US 2026/0149458 A1
(43) Pub. Date: May 28, 2026

(54) DIGITAL TO ANALOG CONVERTER

(71) Applicants: GLOBAL UNICHIP CORPORATION, HSINCHU CITY (TW); TAIWAN SEMICONDUCTOR MANUFACTURING COMPANY, LTD., Hsinchu (TW)

(72) Inventors: Ting-Hao WANG, HSINCHU CITY (TW); Hui-Wen TSAI, HSINCHU CITY (TW)

(21) Appl. No.: 19/078,287

(22) Filed: Mar. 13, 2025

(30) Foreign Application Priority Data
Nov. 26, 2024 (TW) 113145556

(51) Int. Cl. H03M 1/06

(52) U.S. Cl. CPC H03M 1/0607

(57) ABSTRACT

A digital to analog converter includes multiple switching current cells, an offset current cell, and a first amplifier. Each of the switching current cells includes a first differential switch pair, a first stack transistor and a first current source transistor. The first differential switch pair is controlled by a first control signal and a first inverted control signal. The first stack transistor and the first current source transistor are coupled in series and are coupled to the first differential switch pair. The offset current cell includes a second stack transistor. An input terminal of the first amplifier is coupled to a source of the second stack transistor. An output terminal of the first amplifier is coupled to each of a gate of the second stack transistor and a gate of the first stack transistor.

### CROSS-REFERENCE TO RELATED APPLICATIONS

This application claims priority to Taiwan Application Number 113145556, filed Nov. 26, 2024, which is herein incorporated by reference.

### BACKGROUND

### Technical Field

The present disclosure relates to a digital to analog converter, and especially relates to a digital to analog converter with offset current cell.

### Description of Related Art

A digital-to-analog converter (DAC) is a device that converts digital signals into analog signals, allowing the digital signals to be recognized by external systems. In this digital age, DACs are essential components of various electronic devices. However, the digital-to-analog converter can be affected by the equivalent output impedance due to variations at its output, which may lead to poor linearity.

### SUMMARY

The present disclosure provides a digital to analog converter. The digital to analog converter includes multiple switching current cells, an offset current cell, and a first amplifier. Each of the switching current cells includes a first differential switch pair, a first stack transistor and a first current source transistor. The first differential switch pair is controlled by a first control signal and a first inverted control signal. The first stack transistor and the first current source transistor are coupled in series and are coupled to the first differential switch pair. The offset current cell includes a second stack transistor. An input terminal of the first amplifier is coupled to a source of the second stack transistor. An output terminal of the first amplifier is coupled to each of a gate of the second stack transistor and a gate of the first stack transistor.

The present disclosure provides an operation method of a digital to analog converter. The operation method includes: controlling a first differential switch pair controlled by a first control signal and a first inverted control signal, wherein a first stack transistor and a first current source transistor are coupled in series with each other and coupled to the first differential switch pair; controlling a second differential switch pair controlled by a second control signal, wherein a second stack transistor and a second current source transistor are coupled in series with each other and coupled to the second differential switch pair, and a gate of the second current source transistor is coupled to a gate of the first current source transistor. An input terminal of a first amplifier circuit is coupled to a source of the second stack transistor, and an output terminal of the first amplifier circuit is coupled to each of a gate of the second stack transistor and a gate of the first stack transistor, and a current source circuit is coupled to the second current source transistor to form a current mirror, and is coupled to the first current source transistor to form a current mirror.

It is to be understood that both the foregoing general description and the following detailed description are examples, and are intended to provide further explanation of the disclosure as claimed.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1A is a circuit schematic diagram of a digital to analog converter illustrated according to some embodiment of present disclosure.

FIG. 1B is a circuit schematic diagram of a digital to analog converter illustrated according to some embodiment of present disclosure.

FIG. 1C is a circuit schematic diagram of a part of a digital to analog converter in a single side output architecture, illustrated according to some embodiment of present disclosure.

FIG. 2A is a circuit schematic diagram of a digital to analog converter illustrated according to some embodiment of present disclosure.

FIG. 2B is a circuit schematic diagram of a digital to analog converter illustrated according to some embodiment of present disclosure.

### DETAILED DESCRIPTION

Hereinafter multiple embodiments of the present disclosure will be disclosed with schema, as clearly stated, the details in many practices it will be explained in the following description. It should be appreciated, however, that the details in these practices is not applied to limit the present disclosure. Also, it is to say, in some embodiments of the present disclosure, the details in these practices are non-essential. In addition, for the sake of simplifying schema, some known usual structures and element in the drawings by a manner of simply illustrating for it.

Unless otherwise defined, all terms (including technical and scientific terms) used in the present disclosure have the same meaning as commonly understood by the ordinary skilled person to which the concept of the present invention belongs. It will be further understood that terms (such as those defined in commonly used dictionaries) should be interpreted as having a meaning consistent with its meaning in the related technology and/or the context of this specification and not it should be interpreted in an idealized or overly formal sense, unless it is clearly defined as such in this article.

In the present disclosure, when an element is referred to as “connected” or “coupled”, it may mean “electrically connected” or “electrically coupled”. “Connected” or “coupled” can also be used to indicate that two or more components operate or interact with each other.

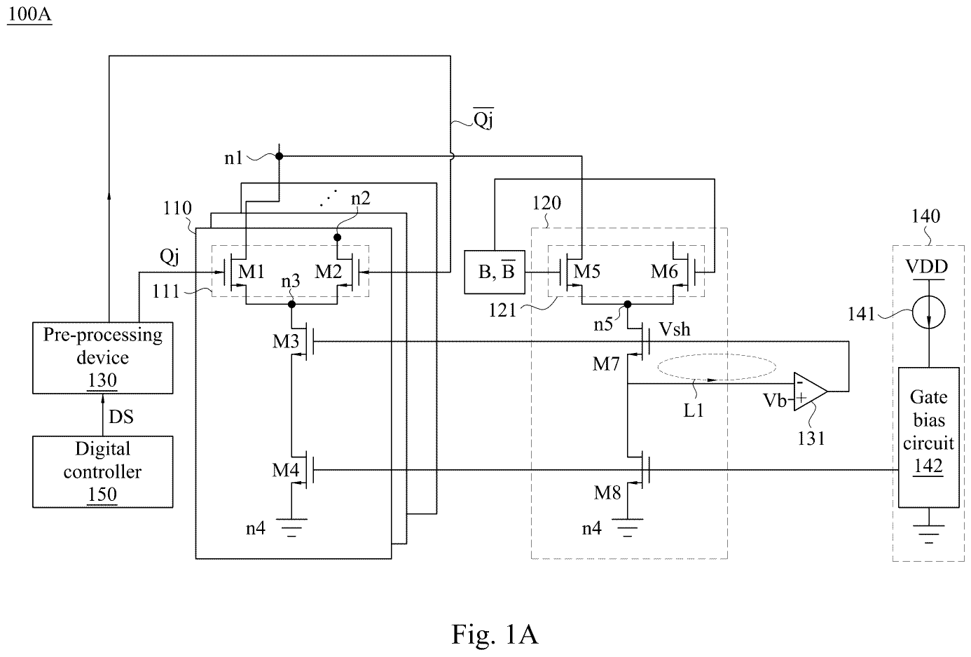

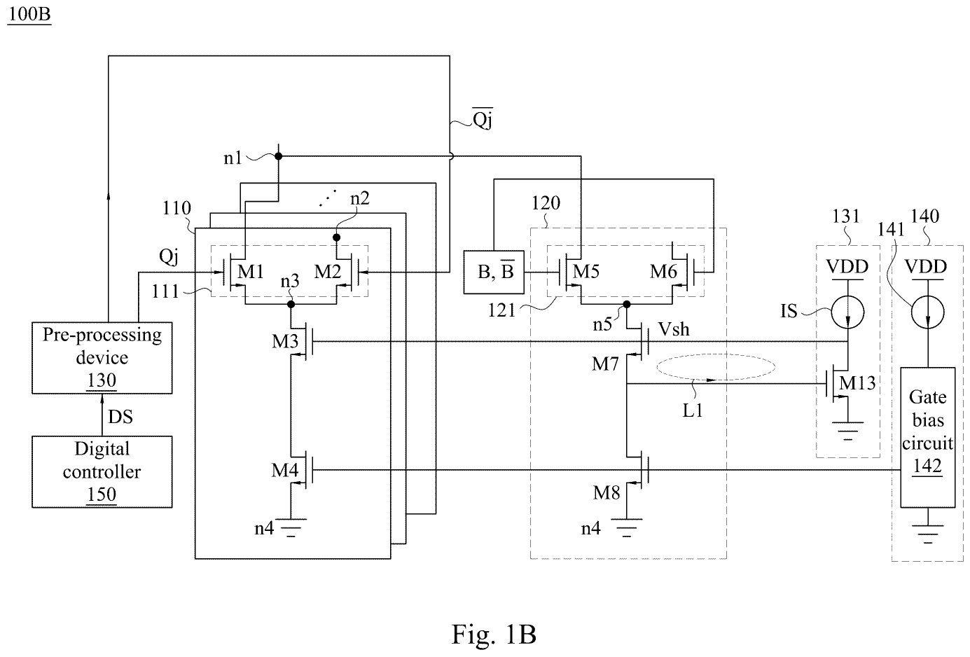

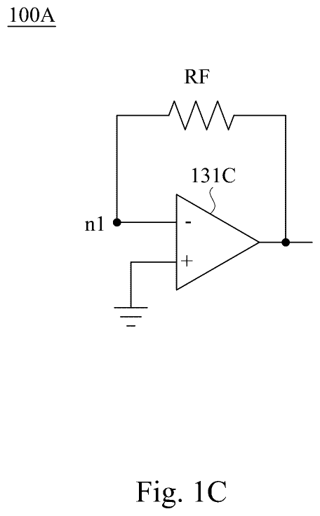

Referring to FIG. 1A, FIG. 1A is a circuit schematic diagram of a digital to analog converter 100A illustrated according to some embodiment of present disclosure. As shown in FIG. 1A, the digital to analog converter 100A includes multiple switching current cells 110, an offset current cell 120, an amplifier circuit 131, a pre-processing device 130, a digital controller 150 and a current source circuit 140.

In some embodiments, the digital controller 150 is configured to generate a digital signal DS. The pre-processing device 130 is configured to convert the digital signal DS into multiple control signals Qj and multiple inverted control signals Q̅j̅. In some embodiments, the control signals Qj and the inverted control signals Q̅j̅ are referred to as differential signal pairs. The multiple switching current cells 110 and the offset current cell 120 are coupled to each other at an output terminal n1, in which the multiple switching current cells 110 correspondingly generate analog signals according to the control signals Qj and the inverted control signals Q̅j̅. The offset current cell 120 is configured to perform offset adjustments to the analog signals outputted by the multiple switching current cells 110. The amplifier circuit 131 is coupled to the multiple switching current cells 110 and the offset current cell 120, and provides gain boosting to increase output impedances of the multiple switching current cells 110. The current source circuit 140 is coupled to the multiple switching current cells 110 and the offset current cell 120, and provides currents required by operations of the multiple switching current cells 110 and the offset current cell 120.

Referring to FIG. 1A, each of the multiple switching current cells 110 includes a differential switch pair 111, a stack transistor M3 and a current source transistor M4. For brevity, FIG. 1A only illustrates detailed configurations of a single switching current cell 110. It should be understood, in following descriptions, otherwise differences are described, the illustrated configurations of the single switching current cell 110 is suitable for each of the multiple switching current cells 110. In which, the differential switch pair 111 includes a switch M1 and a switch M2. The switch M1 and the switch M2 are respectively controlled by the control signal Qj and the inverted control signal Q̅j̅. Specifically, the switch M1 is controlled by one of the control signal Qj and the inverted control signal Q̅j̅, and the switch M2 is controlled by the other one of the control signal Qj and the inverted control signal Q̅j̅.

Furthermore, the control signal Qj and the inverted control signal Q̅j̅ are associated with the digital signal DS. Alternatively stated, the digital signal DS is converted into the control signal Qj and the inverted control signal Q̅j̅ by the pre-processing device 130. Then, the digital to analog converter 100A generates the analog signals according to the control signal Qj and the inverted control signal Q̅j̅. Since the control signal Qj and the inverted control signal Q̅j̅ are inverted with each other, so that when one of the switches M1 and M2 is turned on, the other one of the switches M1 and M2 is turned off.

In some embodiments, the j of the control signal Qj and the inverted control signal Q̅j̅ can present multiple positive integers, and the multiple switching current cells 110 respectively receive the corresponding control signal Qj and the inverted control signal Q̅j̅. For example, the switches M1 and M2 in the first switching current cell 110 are controlled by the control signal Q1 and the inverted control signal Q̅1̅. The switches M1 and M2 in the second switching current cell 110 are controlled by the control signal Q2 and the inverted control signal Q̅2̅, and so on. The switches M1 and M2 in the jth switching current cell 110 are controlled by the control signal Qj and the inverted control signal Q̅j̅.

As shown in FIG. 1A, the switch M1 in the switching current cell 110 is coupled between the output terminal n1 and a node n3, the switch M2 is coupled between an output terminal n2 and the node n3. The stack transistor M3 and the current source transistor M4 coupled in series between the node n3 and a node n4. In which the switch M1, the switch M2, the stack transistor M3 and the current source transistor M4 are NMOS transistors for example. Specifically, a source of the switch M1 and a source of the switch M2 are coupled to each other at the node n3, a drain of the switch M1 is coupled to the output terminal n1, and a drain of the switch M2 is coupled to the output terminal n2. A source of the stack transistor M3 is coupled to a drain of the current source transistor M4. A drain of the stack transistor M3 is coupled to the node n3, and a source of the current source transistor M4 is coupled to the node n4. In some embodiments, the node n4 is a ground terminal.

Referring to FIG. 1A again, similar with the switching current cell 110, the offset current cell 120 includes a differential switch pair 121, a stack transistor M7 and a current source transistor M8. In which, the differential switch pair 121 is controlled by a control signal B.

Specifically, the differential switch pair 121 includes switches M5 and M6. The switch M5 is controlled by a control signal B. In some embodiments, the switch M6 can be controlled by an inverted control signal B̅. in which the inverted control signal B̅ is inverted with the control signal B.

In some embodiments, the control signal B and the inverted control signal B̅ are a fixed differential signal pair. Compared to the control signal Qj and the inverted control signal Q̅j̅ received by the switching current cell 110, the control signal B̅ and the inverted control signal B̅ are maintained unchanged, and the control signal Qj and the inverted control signal Q̅j̅ are changed correspondingly according to the digital signal DS.

Alternatively stated, in some embodiments, the switch M5 is maintained to be turned on, and the switch M6 is maintained to be turned off. In some alternative embodiments, the switch M5 is controlled by the inverted control signal B̅, and the switch M6 is controlled by the control signal B. Alternatively stated, the switch M5 is maintained to be turned off, and the switch M6 is maintained to be turned on.

As shown in FIG. 1A, the switch M5 in the offset current cell 120 is coupled between the output terminal n1 and a node n5, the switch M6 is coupled between an output terminal n2 and the node n5. The stack transistor M7 and the current source transistor M8 coupled in series between the node n5 and the node n4. In which the switch M5, the switch M6, the stack transistor M7 and the current source transistor M8 are NMOS transistors for example. Specifically, a source of the switch M5 and a source of the switch M6 are coupled to each other at the node n5, a drain of the switch M5 is coupled to the output terminal n1, and a drain of the switch M6 is coupled to the output terminal n2. A source of the stack transistor M7 is coupled to a drain of the current source transistor M8. A drain of the stack transistor M7 is coupled to the node n5, and a source of the current source transistor M8 is coupled to the node n4.

Referring to FIG. 1A again, the amplifier circuit 131 is coupled between a gate and the source of the stack transistor M7. Specifically, the amplifier circuit 131 can include an operation amplifier OPA, in which an inverting input terminal of the operation amplifier OPA is coupled to the source of the stack transistor M7, a non-inverting input terminal of the operation amplifier OPA is coupled to a bias signal Vb, and an output terminal of the operation amplifier OPA is coupled to the gate of the stack transistor M7. In FIG. 1A, the inverting input terminal is presented by a symbol −, and the non-inverting input terminal is presented by a symbol +. Under such configuration, a regulated loop L1 is formed between the gate and the source of the stack transistor M7.

Furthermore, the gate of the stack transistor M7 is further coupled to the gate of the stack transistor M3 of each of the switching current cell 110. Correspondingly, the amplifier circuit 131 can provide a voltage signal Vsh to the gate of the stack transistor M3 and the gate of the stack transistor M7. At here, for brevity, FIG. 1A only shows connections of the stack transistor M7 and the single switching current cell 110, but it should be understood, other switching current cells 110 are also coupled to the stack transistor M7 with the same connection. Under such configuration, the output terminal of the amplifier circuit 131 is coupled to the gate of the stack transistor M7, and is coupled to the gate of the stack transistor M3 of each of the switching current cell 110 through the gate of the stack transistor M7. As such, the amplifier circuit 131 can provide gain, to further respectively increase a total impedance of the stack transistor M3 and the current source transistor M4 and a total impedance of the stack transistor M7 and the current source transistor M8, to further increase the output impedance of the switching current cell 110 and the offset current cell 120.

Referring to FIG. 1A again, in some embodiments, a gate of the current source transistor M8 is further coupled to the gate of the current source transistor M4 of each of the switching current cell 110. At here, for brevity, FIG. 1A only shows connections of the current source transistor M8 and the single switching current cell 110, but it should be understood, other switching current cells 110 are also coupled to the current source transistor M8 with the same connection.

As shown in FIG. 1A, the current source circuit 140 is coupled with the current source transistor M8 to form a current mirror. As such, the current source transistor M8 can be turned on according to the current source circuit 140 to generate a mirror current. At the same moment, the current source circuit 140 is also coupled with each current source transistor M4 in the multiple switching current cells 110 to form current mirrors. As such, each current source transistor M4 can be turned on according to the current source circuit 140 to generate mirror currents.

In some embodiments, the current source circuit 140 can include a current source 141 and a gate bias circuit 142. A terminal of the current source 141 is configured to receive a power voltage VDD, and another terminal of the current source 141 is coupled to the gate bias circuit 142. The gate bias circuit 142 is coupled to the ground terminal, and configured to provide a gate bias voltage to the gates of the current source transistors M4 and M8.

In some embodiments, the gate bias circuit 142 can be implemented by a transistor (not shown in the figures). A gate of this transistor is coupled to the gates of the current source transistors M4 and M8. A drain of this transistor is coupled to the gate of this transistor and the current source 141. A source of this transistor is coupled to the ground terminal.

In various embodiments, the digital to analog converter 100A can output the analog signals from the output terminals n1 and the output terminals n2 in various ways. For example, the digital to analog converter 100A can be implemented by a single side output architecture. FIG. 1C is a circuit schematic diagram of a part of a digital to analog converter in a single side output architecture, illustrated according to some embodiment of present disclosure. As shown in FIG. 1C, in the single side output architecture, the digital to analog converter 100A further includes an operation amplifier 131C and an output resistor RF. An inverting input terminal of the operation amplifier 131C is coupled to the output node n1. A non-inverting input terminal of the operation amplifier 131C is coupled to the ground terminal or a fixed bias voltage. The output resistor RF is coupled between the output node n1 and an output terminal of this operation amplifier 131C.

In the example described above, the multiple switching current cells 110 are configured to generate multiple output currents I1 flowing through the switches M1 and multiple output currents I2 flowing through the switches M2. A summation of the output currents I1 is determined by a turned-on number of the switches M1 and the switch M5 maintained to be turned on. A summation of the output currents I2 is determined by a turned-on number of the switches M2 and the switch M6. As a result, the digital to analog converter 100A can generate an output voltage, in which the output voltage is equal to the summation of the output currents I1 multiplied by the output resistor RF.

For another example, the digital to analog converter 100A can be implemented by a dual side output architecture. In the dual side output architecture, the digital to analog converter 100A can further include a load resistor (not shown in the figures). The load resistor can include a resistor R1 and a resistor R2 (not shown in the figures). Specifically, the resistor R1 is coupled to the multiple switching current cells 110 at the output terminal n1, and the resistor R2 is coupled to the multiple switching current cells 110 at the output terminal n2. In some embodiments, the resistor R1 and the resistor R2 have the same resistance. Furthermore, in another embodiment, the load resistor can only include the resistor R1. At this moment, the resistor R1 is coupled to the output terminal n1, and the output terminal n2 is changed to the ground terminal.

In the example described above, the multiple switching current cells 110 are configured to generate multiple output currents I1 flowing through the switches M1 and multiple output currents I2 flowing through the switches M2. A summation of the output currents I1 is determined by a turned-on number of the switches M1 and the switch M5 maintained to be turned on. A summation of the output currents I2 is determined by a turned-on number of the switches M2 and the switch M6. The summation of the output currents I1 and the summation of the output currents I2 respectively flow through the resistors R1 and R2, to generate output voltage differences at the output terminal n1 and the output terminal n2.

Referring to FIG. 1B, FIG. 1B is a circuit schematic diagram of a digital to analog converter 100B illustrated according to some embodiment of present disclosure. Compared to the digital to analog converter 100A shown in FIG. 1A, a main difference is that, the amplifier circuit 131 of the digital to analog converter 100B includes a transistor M13 and a current source IS. In which, the transistor M13, the switches M1-M2, the switches M5-M6, the stack transistor M3, the stack transistor M7, the current source transistor M4 and the current source transistor M8 are NMOS transistors for example. Specifically, a drain of the transistor M13 is coupled to the current source IS and the gate of the stack transistor M7. A gate of the transistor M13 is coupled to the source of the stack transistor M7. As such, the amplifier circuit 131 can provide gain, to further respectively increase a total impedance of the stack transistor M3 and the current source transistor M4 and a total impedance of the stack transistor M7 and the current source transistor M8, to further increase the output impedance of the switching current cell 110 and the offset current cell 120.

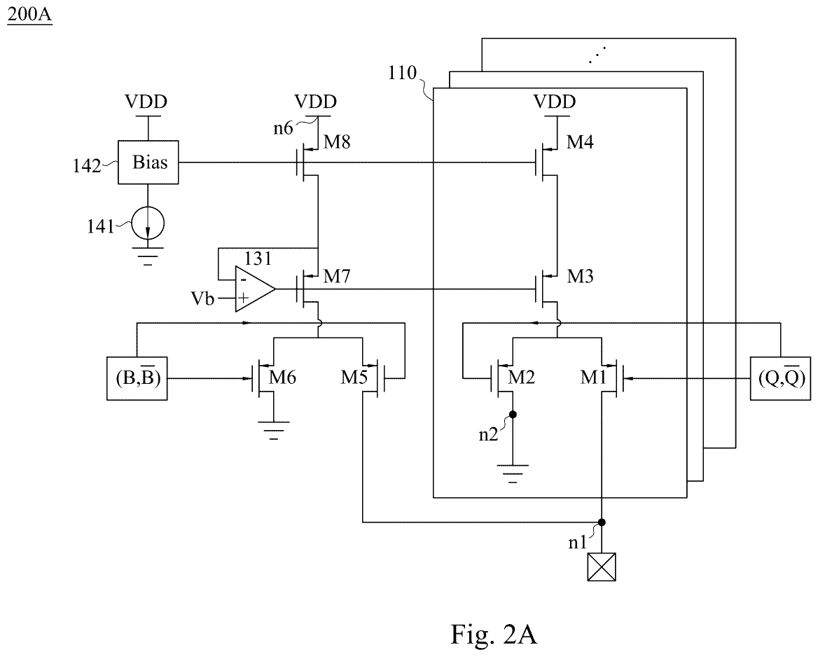

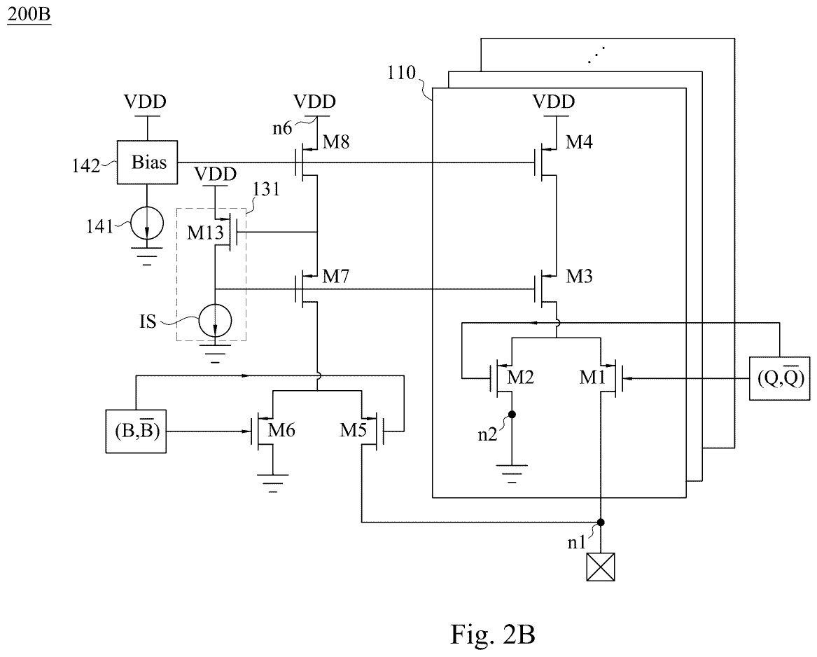

References are made to FIG. 2A. FIG. 2A is a circuit schematic diagram of a digital to analog converter 200A illustrated according to some embodiment of present disclosure. Referring to FIG. 1A and FIG. 2A, the digital to analog converter 200A is an alternative embodiment of the digital to analog converter 100A. The digital to analog converter 200A follows a similar labeling convention to that of the digital to analog converter 100A. For brevity, the discussion will focus more on differences between the digital to analog converter 200A and the digital to analog converter 100A than on similarities.

In the embodiments corresponding to FIG. 2A, the source of the current source transistor M4 and the source of the current source transistor M8 are coupled to the power voltage VDD at a node n6. The drain of the switch M2 and the drain of the switch M6 are coupled to the ground terminal at the output terminal n2. In which, the switches M1-M2, the switches M5-M6, the stack transistor M3, the stack transistor M7, the current source transistor M4 and the current source transistor M8 are PMOS transistors for example.

References are made to FIG. 2B. FIG. 2B is a circuit schematic diagram of a digital to analog converter 200B illustrated according to some embodiment of present disclosure. Compared to the digital to analog converter 200A shown in FIG. 2A, a main difference is that, the amplifier circuit 131 of the digital to analog converter 200B includes a transistor M13 and a current source IS. In which, the transistor M13, the switches M1-M2, the switches M5-M6, the stack transistor M3, the stack transistor M7, the current source transistor M4 and the current source transistor M8 are PMOS transistors for example. Specifically, a drain of the transistor M13 is coupled to the current source IS and the gate of the stack transistor M7. A gate of the transistor M13 is coupled to the source of the stack transistor M7. As such, the amplifier circuit 131 can provide gain, to further respectively increase a total impedance of the stack transistor M3 and the current source transistor M4 and a total impedance of the stack transistor M7 and the current source transistor M8, to further increase the output impedance of the switching current cell 110 and the offset current cell 120.

In the embodiments corresponding to FIG. 2B, a terminal of the current source 141 is coupled to the ground terminal, and another terminal of the current source 141 is coupled to the gate bias circuit 142. The gate bias circuit 142 is configured to receive the power voltage VDD, and provide a gate bias voltage to the gates of the current source transistors M4 and M8.

In summary, the technical means of the present disclosure can increase the output impedances of the digital to analog converters with a lower cost, and can help to improve the linearity of the digital to analog converters.

Although the present disclosure has been described in considerable detail with reference to certain embodiments thereof, other embodiments are possible. Therefore, the spirit and scope of the appended claims should not be limited to the description of the embodiments contained herein.

It will be apparent to those skilled in the art that various modifications and variations can be made to the structure of the present disclosure without departing from the scope or spirit of the disclosure. In view of the foregoing, it is intended that the present disclosure cover modifications and variations of this disclosure provided they fall within the scope of the following claims.

What is claimed is:

1. A digital to analog converter, comprising:
a plurality of switching current cells, each of the plurality of switching current cells comprising:
a first differential switch pair controlled by a first control signal and a first inverted control signal; and
a first stack transistor and a first current source transistor coupled in series with each other and coupled to the first differential switch pair;
an offset current cell, comprising:
a second differential switch pair controlled by a second control signal; and
a second stack transistor and a second current source transistor coupled in series with each other and coupled to the second differential switch pair, wherein a gate of the second current source transistor is coupled to a gate of the first current source transistor;
a first amplifier circuit, an input terminal of the first amplifier circuit being coupled to a source of the second stack transistor, and an output terminal of the first amplifier circuit being coupled to each of a gate of the second stack transistor and a gate of the first stack transistor; and
a current source circuit coupled to the second current source transistor to form a current mirror, and coupled to the first current source transistor to form a current mirror.

2. The digital to analog converter of claim 1, wherein the first amplifier circuit comprises:
an operation amplifier, wherein an inverting input terminal of the operation amplifier is coupled to the source of the second stack transistor, a non-inverting input terminal of the operation amplifier is coupled to a bias signal, and an output terminal of the operation amplifier is coupled to each of the gate of the second stack transistor and the gate of the first stack transistor.

3. The digital to analog converter of claim 1, wherein the first amplifier circuit comprises:
a first transistor, a drain of the first transistor being coupled to each of the gate of the second stack transistor and the gate of the first stack transistor, and a gate of the first transistor being coupled to the source of the second stack transistor; and
a first current source coupled to the drain of the first transistor.

4. The digital to analog converter of claim 1, wherein the first differential switch pair comprises:
a first switch, a first terminal of the first switch being coupled to a first output terminal, and a second terminal of the first switch being coupled to the first stack transistor at a first node; and
a second switch, a first terminal of the second switch being coupled to a second output terminal, and a second terminal of the second switch being coupled to the first stack transistor at the first node.

5. The digital to analog converter of claim 4, wherein the second differential switch pair comprises:
a third switch controlled by the second control signal, a first terminal of the third switch being coupled to the first output terminal, and a second terminal of the third switch being coupled to the second stack transistor at a second node; and
a fourth switch controlled by a second inverted control signal, and being coupled to the second node,
wherein the second control signal and the second inverted control signal are maintained unchanged.

6. The digital to analog converter of claim 4, further comprising:
an operation amplifier; and
an output resistor,
wherein an inverting input terminal of the operation amplifier is coupled to the first output terminal, a non-inverting input terminal of the operation amplifier is coupled to a ground terminal or a fixed bias voltage, and
the output resistor is coupled between the first output terminal and an output terminal of the operation amplifier.

7. The digital to analog converter of claim 4, further comprising:
a load resistor, the load resistor comprising:
a first resistor coupled to the first output terminal.

8. The digital to analog converter of claim 7, wherein the load resistor further comprising:
a second resistor coupled to the second output terminal.

9. The digital to analog converter of claim 1, wherein the first current source transistor is coupled to a ground terminal.

10. The digital to analog converter of claim 1, wherein the first current source transistor is configured to receive a power voltage.

11. An operation method of a digital to analog converter, comprising:
controlling a first differential switch pair controlled by a first control signal and a first inverted control signal, wherein a first stack transistor and a first current source transistor are coupled in series with each other and coupled to the first differential switch pair; and
controlling a second differential switch pair controlled by a second control signal, wherein a second stack transistor and a second current source transistor are coupled in series with each other and coupled to the second differential switch pair, and a gate of the second current source transistor is coupled to a gate of the first current source transistor,
wherein an input terminal of a first amplifier circuit is coupled to a source of the second stack transistor, and an output terminal of the first amplifier circuit is coupled to each of a gate of the second stack transistor and a gate of the first stack transistor, and
a current source circuit is coupled to the second current source transistor to form a current mirror, and is coupled to the first current source transistor to form a current mirror.

12. The operation method of claim 11, wherein the first amplifier circuit comprises an operation amplifier,
an inverting input terminal of the operation amplifier is coupled to the source of the second stack transistor, a non-inverting input terminal of the operation amplifier is coupled to a bias signal, and
an output terminal of the operation amplifier is coupled to each of the gate of the second stack transistor and the gate of the first stack transistor.

13. The operation method of claim 11, wherein the first amplifier circuit comprises a first transistor and a first current source,
a drain of the first transistor being coupled to each of the gate of the second stack transistor and the gate of the first stack transistor, and a gate of the first transistor being coupled to the source of the second stack transistor, and
the first current source is coupled to the drain of the first transistor.

14. The operation method of claim 11, wherein the first differential switch pair comprises a first switch and a second switch,
a first terminal of the first switch being coupled to a first output terminal, and a second terminal of the first switch being coupled to the first stack transistor at a first node, and
a first terminal of the second switch being coupled to a second output terminal, and a second terminal of the second switch being coupled to the first stack transistor at the first node.

15. The operation method of claim 14, further comprising:
controlling a third switch in the second differential switch pair by the second control signal, wherein a first terminal of the third switch is coupled to the first output terminal, and a second terminal of the third switch is coupled to the second stack transistor at a second node;
controlling a fourth switch in the second differential switch pair by a second inverted control signal, wherein the fourth switch is coupled to the second node; and
maintaining the second control signal and the second inverted control signal being unchanged.

16. The operation method of claim 14, wherein an inverting input terminal of an operation amplifier is coupled to the first output terminal, a non-inverting input terminal of the operation amplifier is coupled to a ground terminal or a fixed bias voltage, and
an output resistor is coupled between the first output terminal and an output terminal of the operation amplifier.

17. The operation method of claim 14, wherein a load resistor comprises a first resistor coupled to the first output terminal.

18. The operation method of claim 17, wherein the load resistor further comprises a second resistor coupled to the second output terminal.

19. The operation method of claim 11, wherein the first current source transistor is coupled to a ground terminal.

20. The operation method of claim 11, further comprising:
receiving a power voltage by the first current source transistor.
